(19) United States
(12) Patent Application Publication
(10) Pub. No.: US 2026/0171355 A1
(43) Pub. Date: Jun. 18, 2026

(54) MULTI-CHARGED PARTICLE BEAM WRITING METHOD, AND MULTI-CHARGED PARTICLE BEAM WRITING APPARATUS

(71) Applicant: NuFlare Technology, Inc., Yokohama-shi (JP)

(72) Inventor: Hiroshi MATSUMOTO, Yokohama-shi (JP)

(73) Assignee: NuFlare Technology, Inc., Yokohama-shi (JP)

(21) Appl. No.: 19/344,762

(22) Filed: Sep. 30, 2025

(30) Foreign Application Priority Data
Dec. 13, 2024 (JP) 2024-218354

(51) Int. Cl. H01J 37/304; G03F 7/00; H01J 37/317

(52) U.S. Cl. CPC H01J 37/304; G03F 7/7015; G03F 7/70391; G03F 7/704; G03F 7/70508; G03F 7/70516; G03F 7/70558; H01J 37/3177; H01J 2237/30472; H01J 2237/31774

(57) ABSTRACT

A multi-charged-particle-beam writing method includes calculating a magnification correction amount of an acquired beam array shape by using a first coefficient indicating a displacement component which deviates in a first direction in proportion to a design coordinate in the first direction of the acquired beam array shape, where the first direction is parallel to a direction of writing performed while continuously moving a stage with a target object thereon; calculating a rotation correction amount of the acquired beam array shape by using a second coefficient indicating a displacement component which deviates in a second direction, being orthogonal to the first direction, in proportion to a design coordinate in the first direction of the acquired beam array shape; and calculating a modulation dose amount for each unit region of a plurality of unit regions, based on at least one of a third coefficient, and a fourth coefficient.

### CROSS-REFERENCE TO RELATED APPLICATION

This application is based upon and claims the benefit of priority from prior Japanese Patent Application No. 2024-218354 filed on Dec. 13, 2024 in Japan, the entire contents of which are incorporated herein by reference.

### BACKGROUND OF THE INVENTION

### Field of the Invention

Embodiments of the present invention relate to a multiple charged particle beam writing method and a multiple charged particle beam writing apparatus, and, for example, to a method for correcting a positional deviation of a beam array occurring on the substrate surface of a multiple beam writing apparatus.

### Description of Related Art

The lithography technique which advances miniaturization of semiconductor devices is extremely important as a unique process in which patterns are formed in semiconductor manufacturing. In recent years, with high integration of LSI, the line width (critical dimension) necessary for semiconductor device circuits is decreasing year by year. The electron beam writing technique, which intrinsically has excellent resolution, is used for writing or “drawing” patterns on a wafer and the like with electron beams.

For example, as a known example of employing the electron beam writing technique, there is a writing apparatus using multiple beams. Since writing with multiple beams can apply a lot of beams at a time, the writing throughput can be greatly increased compared to writing with a single electron beam. For example, a writing apparatus employing the multiple-beam system forms multiple beams by letting an electron beam emitted from an electron gun pass through a mask having a plurality of holes, performs blanking control for each beam, reduces each unblocked beam to generate a reduced mask image by an optical system, and deflects, by a deflector, a reduced beam to be applied to a desired position on a target object or “sample”.

With regard to the multiple beam writing, it is important for the writing precision to highly accurately connect (combine) beam arrays each other which are applied to the substrate. Accordingly, before writing, mark scanning is performed in order to measure a beam array shape on the substrate (e.g., refer to Japanese Patent Application Laid-open (JP-A) No. 2017-220615). Regarding deviation of the beam array shape, linear components can be corrected by adjusting intensity and distribution of the magnetic field by a magnetic lens, etc. However, although measurement for confirmation of the shape is performed after correcting the beam array shape because magnetic elements have hysteresis, if in that case there is deviation, readjustment is needed. The measurement of the beam array shape takes about several ten minutes. Additionally, the shape correction takes about several ten minutes. Since the apparatus cannot be operated during the processing described above, a problem occurs that the operating rate of the apparatus is greatly affected.

### BRIEF SUMMARY OF THE INVENTION

According to one aspect of the present invention, a multi-charged particle beam writing method includes
acquiring a beam array shape of multiple charged particle beams,
calculating a magnification correction amount of an acquired beam array shape by using a first coefficient indicating a displacement component which deviates in a first direction in proportion to a design coordinate in the first direction of the acquired beam array shape, where the first direction is parallel to a direction of writing performed while continuously moving a stage with a target object thereon,
calculating a rotation correction amount of the acquired beam array shape by using a second coefficient indicating a displacement component which deviates in a second direction, being orthogonal to the first direction, in proportion to a design coordinate in the first direction of the acquired beam array shape,
calculating a modulation dose amount for each unit region of a plurality of unit regions obtained by dividing a stripe region of the target object into mesh regions, based on at least one of a third coefficient indicating a displacement component which deviates in the first direction in proportion to a design coordinate in the second direction of the acquired beam array shape, and a fourth coefficient indicating a displacement component which deviates in the second direction in proportion to a design coordinate in the second direction of the acquired beam array shape,
performing, using at least two objective lenses, at least one of rotation correction, corresponding to the rotation correction amount, of the acquired beam array shape, and magnification correction, corresponding to the magnification correction amount, of the acquired beam array shape, and performing modulation of a dose amount for the each unit region by using the modulation dose amount, and
writing a pattern on the target object with the multiple charged particle beams for which the modulation of the dose amount and at least the one of the rotation correction of the acquired beam array shape and the magnification correction of the acquired beam array shape have been performed.

According to another aspect of the present invention, a multi-charged particle beam writing apparatus includes
an emission source configured to emit multiple charged particle beams,
an acquisition circuit configured to acquire a beam array shape of the multiple charged particle beams,
a magnification correction amount calculation circuit configured to calculate a magnification correction amount of an acquired beam array shape by using a first coefficient indicating a displacement component which deviates in a first direction in proportion to a design coordinate in the first direction of the acquired beam array shape, where the first direction is parallel to a direction of writing performed while continuously moving a stage with a target object thereon,
a rotation correction amount calculation circuit configured to calculate a rotation correction amount of the acquired beam array shape by using a second coefficient indicating a displacement component which deviates in a second direction, being orthogonal to the first direction, in proportion to a design coordinate in the first direction of the acquired beam array shape,
a modulation dose amount calculation circuit configured to calculate a modulation dose amount for each unit region of a plurality of unit regions obtained by dividing a stripe region of the target object into mesh regions, based on at least one of a third coefficient indicating a displacement component which deviates in the first direction in proportion to a design coordinate in the second direction of the acquired beam array shape, and a fourth coefficient indicating a displacement component which deviates in the second direction in proportion to a design coordinate in the second direction of the acquired beam array shape,
a dose modulation circuit configured to perform modulation of a dose amount for the each unit region by using the modulation dose amount,
an objective lens configured to perform at least one of magnification correction, corresponding to the magnification correction amount, of the acquired beam array shape, and rotation correction, corresponding to the rotation correction amount, of the acquired beam array shape, and
a writing mechanism configured to write a pattern on the target object with the multiple charged particle beams for which the modulation of the dose amount and at least the one of the magnification correction of the acquired beam array shape and the rotation correction of the acquired beam array shape have been performed.

### BRIEF DESCRIPTION OF THE DRAWINGS

FIG. 1 is an illustration showing a schematic diagram of a configuration of a writing apparatus according to a first embodiment;

FIG. 2 is a conceptual diagram showing a configuration of a shaping aperture array substrate according to the first embodiment;

FIG. 3 is a sectional view showing a configuration of a blanking aperture array mechanism according to the first embodiment;

FIG. 4 is a conceptual diagram showing an example of writing operations according to the first embodiment;

FIG. 5 is an illustration showing an example of an irradiation region of multiple beams and a writing target pixel according to the first embodiment;

FIG. 6 is an illustration showing a parameter of a linear component according to the first embodiment;

FIG. 7 is a flowchart showing an example of main steps of a writing method according to the first embodiment;

FIG. 8 is an illustration showing an example of a relation table according to the first embodiment;

FIG. 9 is an illustration showing an example of a beam position according to the first embodiment;

FIG. 10 is an illustration for explaining a rotation amount θ and a magnification m of a beam array shape according to the first embodiment;

FIG. 11 is an illustration showing an example of a state where rotation correction and magnification correction of a beam array have been performed according to the first embodiment;

FIG. 12 is an illustration explaining a method for correcting a YY term component according to the first embodiment;

FIG. 13 is an illustration explaining a method for correcting an XY term component according to the first embodiment;

FIG. 14 is an illustration for explaining an example of a multiple beam writing operation according to the first embodiment;

FIG. 15 is an illustration showing an example of a position deviation state in the case of writing according to the first embodiment;

FIG. 16 is a conceptual diagram showing a configuration of a writing apparatus according to a second embodiment; and

FIG. 17 is an illustration showing an example of a relation table according to the second embodiment.

### DETAILED DESCRIPTION OF THE INVENTION

Embodiments below provide a writing method and writing apparatus that can reduce positional deviation due to displacement of a linear component of a beam array shape in multiple beam writing.

Embodiments below describe a configuration in which an electron beam is used as an example of a charged particle beam. The charged particle beam is not limited to the electron beam, and other charged particle beams such as an ion beam may also be used.

### First Embodiment

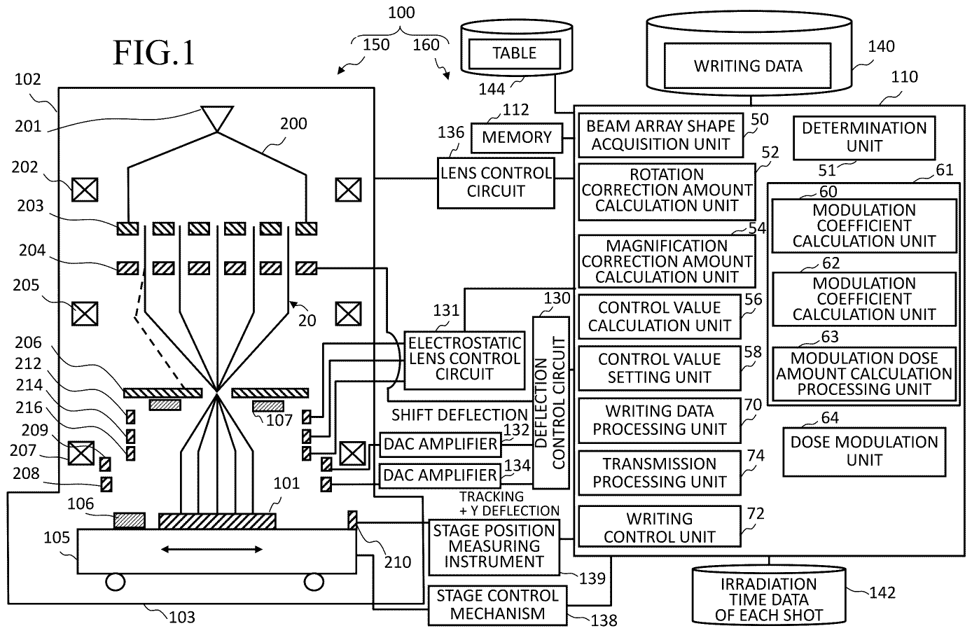

FIG. 1 is an illustration showing a schematic diagram of a configuration of a writing or “drawing” apparatus according to a first embodiment. As shown in FIG. 1, a writing apparatus 100 includes a writing mechanism 150 and a control system circuit 160. The writing apparatus 100 is an example of a multi-charged particle beam writing apparatus and a multi-charged particle beam exposure apparatus. The writing mechanism 150 includes an electron optical column 102 (electron beam column) and a writing chamber 103. In the electron optical column 102, there are disposed an electron gun 201, an illumination lens 202, a shaping aperture array substrate 203, a blanking aperture array mechanism 204, a reducing lens 205, a limiting aperture substrate 206, an electromagnetic lens 207 being an objective lens, a main deflector 208, a sub deflector 209, a detector 107, and electrostatic lenses 212, 214, and 216 being a plurality of objective lenses.

In the writing chamber 103, an XY stage 105 is disposed. On the XY stage 105, there is placed a target object or “sample” 101 such as a mask serving as a writing target substrate when writing (exposure) is performed. The target object 101 is, for example, an exposure mask used in fabricating semiconductor devices, or a semiconductor substrate (silicon wafer) for fabricating semiconductor devices. Moreover, the target object 101 may be, for example, a mask blank on which resist has been applied and nothing has yet been written. On the XY stage 105, a mirror 210 for measuring the position of the XY stage 105 is placed.

Furthermore, on the XY stage 105, a mark 106 for measuring a beam position is arranged. The mark 106 may be a transmission type or a reflection type. If the mark 106 is a reflection type, a secondary electron emitted when the mark 106 is irradiated with a beam by the detector 107 arranged above the mark is detected. The mark pattern may be the same as a conventional one. For example, preferably, a dot pattern or a cross pattern is used. If the mark 106 is a transmission type, an electron beam is detected by a detector (not shown) in the mark 106. In the case of the mark 106 being a transmission type, an aperture for detecting beams one by one or some by some is formed on the upper surface of the mark 106.

The control system circuit 160 includes a control computer 110, a memory 112, a deflection control circuit 130, an electrostatic lens control circuit 131, DAC (digital-analog converter) amplifier units 132 and 134, a lens control circuit 136, a stage control mechanism 138, a stage position measuring instrument 139, and storage devices 140, 142, and 144 such as magnetic disk drives. The control computer 110, the memory 112, the deflection control circuit 130, the electrostatic lens control circuit 131, the lens control circuit 136, the stage control mechanism 138, the stage position measuring instrument 139, and the storage devices 140, 142, and 144 are connected to each other through a bus (not shown). The DAC amplifier units 132 and 134 and the blanking aperture array mechanism 204 are connected to the deflection control circuit 130. The sub deflector 209 is composed of at least four electrodes (or “at least four poles”), and controlled by the deflection control circuit 130 through the DAC amplifier unit 132 disposed for each electrode. The main deflector 208 is composed of at least four electrodes (or “at least four poles”), and controlled by the deflection control circuit 130 through the DAC amplifier unit 134 disposed for each electrode. Lenses such as the illumination lens 202, the reducing lens 205, and the objective lens (electromagnetic lens) 207 are controlled by the lens control circuit 136.

Each of a plurality of electrostatic lenses 212, 214, and 216 is composed of three or more stage electrode substrates each having an opening at the center part. The upper and lower stage electrode substrates are applied with ground potentials, and the middle stage one is applied with a control potential V. Each of the electrostatic lenses 212, 214, and 216 is controlled by the electrostatic lens control circuit 131. Although, in FIG. 1 and others, the case of using three electrostatic lenses 212, 214, and 216 is described, it is not limited thereto. In the case where a focus deviation due to rotation correction and magnification correction of a beam array is within a tolerance, or where a focus deviation is ignored, it is sufficient, omitting the electrostatic lens 216, to arrange the electrostatic lenses 212 and 214 of two stages. Thus, it is sufficient to arrange electrostatic lenses of two or more stages.

The position of the XY stage 105 is controlled by the drive of each axis motor (not shown) which is controlled by the stage control mechanism 138. Based on the principle of laser interferometry, the stage position measurement instrument 139 measures the position of the XY stage 105 by receiving a reflected light from the mirror 210.

The signal detected by the detector 107 is converted into digital data in a detection circuit (not shown), and output to the control computer 110.

In the control computer 110, there are arranged a beam array shape acquisition unit 50, a determination unit 51, a rotation correction amount calculation unit 52, a magnification correction amount calculation unit 54, a control value calculation unit 56, a control value setting unit 58, a modulation dose amount calculation unit 61, a dose modulation unit 64, a writing data processing unit 70, a writing control unit 72, and a transmission processing unit 74. The modulation dose amount calculation unit 61 includes a modulation coefficient calculation unit 60, a modulation coefficient calculation unit 62, and a modulation dose amount calculation processing unit 63. Each of the “ . . . units” such as the beam array shape acquisition unit 50, determination unit 51, rotation correction amount calculation unit 52, magnification correction amount calculation unit 54, control value calculation unit 56, control value setting unit 58, modulation dose amount calculation unit 61 (modulation coefficient calculation unit 60, modulation coefficient calculation unit 62, and modulation dose amount calculation processing unit 63), dose modulation unit 64, writing data processing unit 70, writing control unit 72, and transmission processing unit 74 includes processing circuitry. The processing circuitry includes, for example, an electric circuit, a computer, a processor, a circuit board, a quantum circuit, a semiconductor device, or the like. Each “ . . . unit” may use common processing circuitry (the same processing circuitry), or different processing circuitry (separate processing circuitry). Information input/output to/from the beam array shape acquisition unit 50, determination unit 51, rotation correction amount calculation unit 52, magnification correction amount calculation unit 54, control value calculation unit 56, the control value setting unit 58, modulation dose amount calculation unit 61 (modulation coefficient calculation unit 60, modulation coefficient calculation unit 62, and modulation dose amount calculation processing unit 63), dose modulation unit 64, writing data processing unit 70, writing control unit 72, and transmission processing unit 74, and information being operated are stored in the memory 112 each time.

Writing operations of the writing apparatus 100 are controlled by the writing control unit 72. Processing of transmitting irradiation time data of each shot to the deflection control circuit 130 is controlled by the transmission processing unit 74.

Writing data (chip data) is input from the outside of the writing apparatus 100, and stored in the storage device 140. Chip data defines information on a plurality of figure patterns configuring a chip pattern. Specifically, for example, a figure code, coordinates, a size, and the like are defined for each figure pattern.

FIG. 1 shows a configuration necessary for describing the first embodiment. Other configuration elements generally necessary for the writing apparatus 100 may also be included therein.

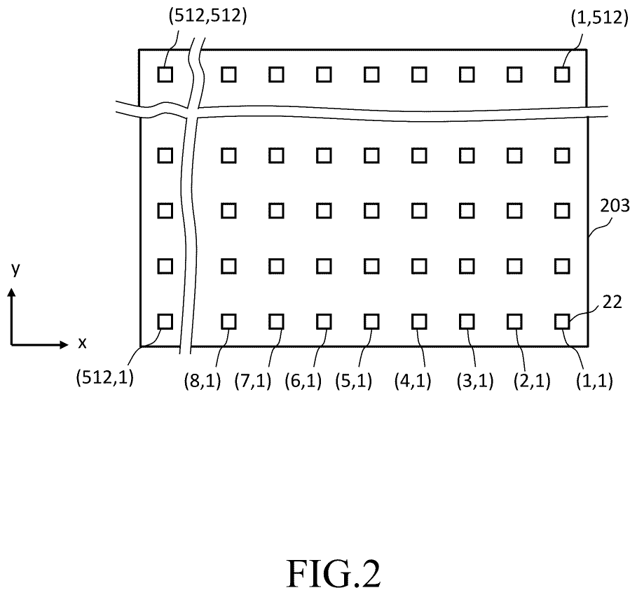

FIG. 2 is a conceptual diagram showing a configuration of a shaping aperture array substrate according to the first embodiment. As shown in FIG. 2, holes (openings) 22 of p columns wide (width in the x direction) and q rows long (length in the y direction) (p≥2, q≥2) are formed, like a matrix, at a predetermined arrangement pitch in the shaping aperture array substrate 203. In the case of FIG. 2, for example, holes 22 of 512×512, that is 512 holes in the y direction and 512 holes in the x direction, are formed. The number of holes 22 is not limited thereto. For example, it is also preferable to form the holes 22 of 32×32. Each of the holes 22 is a rectangle (including a square) having the same dimension and shape as each other. Alternatively, each of the holes 22 may be a circle with the same diameter as each other. The multiple beams 20 are formed by letting portions of an electron beam 200 individually pass through a corresponding one of a plurality of holes 22. In other words, the shaping aperture array substrate 203 forms and emits the multiple beams 20. The shaping aperture array substrate 203 serves as an example of an emission source of the multiple beams 20 or a multiple beams forming mechanism.

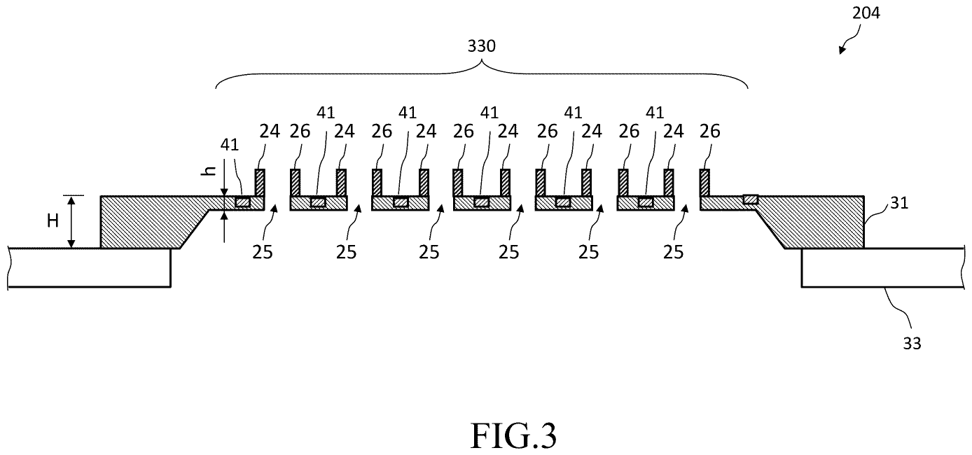

FIG. 3 is a sectional view showing a configuration of a blanking aperture array mechanism according to the first embodiment. In the blanking aperture array mechanism 204, as shown in FIG. 3, a blanking aperture array substrate 31 being a semiconductor substrate made of silicon, etc. is disposed on a support table 33. In a membrane region 330 at the center of the blanking aperture array substrate 31, a plurality of passage holes 25 (openings), through each of which a corresponding one of the multiple beams 20 passes, are formed at positions each corresponding to each hole 22 in the shaping aperture array substrate 203 shown in FIG. 2. A pair of a control electrode 24 and a counter electrode 26, (blanker: blanking deflector), is arranged in a manner such that the electrodes 24 and 26 are opposite to each other across a corresponding one of the plurality of the passage holes 25. A control circuit 41 (logic circuit) which applies a deflection voltage to the control electrode 24 for the passage hole 25 concerned is disposed, inside the blanking aperture array substrate 31, close to each corresponding passage hole 25. The counter electrode 26 for each beam is grounded.

In the control circuit 41, an amplifier (not shown) (an example of a switching circuit) is arranged. As an example of the amplifier, a CMOS (Complementary MOS) inverter circuit serving as a switching circuit is disposed. With regard to inputs (IN) to the CMOS inverter circuit, either an L (low) potential (e.g., ground potential) lower than a threshold voltage, or an H (high) potential (e.g., 1.5 V) higher than or equal to the threshold voltage is applied as a control signal. According to the first embodiment, in a state where an L potential is applied to the input (IN) of the CMOS inverter circuit, the output (OUT) of the CMOS inverter circuit, which is to be applied to the control circuit 41, becomes a positive potential (Vdd), and then, a corresponding beam is deflected by an electric field due to a potential difference from the ground potential of the counter electrode 26, and is controlled to be in a beam OFF condition by being blocked by the limiting aperture substrate 206. In contrast, in a state (active state) where an H potential is applied to the input (IN) of the CMOS inverter circuit, the output (OUT) of the CMOS inverter circuit becomes a ground potential, and therefore, since there is no potential difference from the ground potential of the counter electrode 26, a corresponding beam is not deflected, and is controlled to be in a beam ON condition by passing through the limiting aperture substrate 206. Blanking control is provided by such deflection.

Next, operations of the writing mechanism 150 will be described. The electron beam 200 emitted from the electron gun 201 (emission source) almost perpendicularly (e.g., vertically) illuminates the whole of the shaping aperture array substrate 203 by the illumination lens 202. A plurality of rectangular holes 22 (openings) are formed in the shaping aperture array substrate 203. The region including all of the plurality of holes 22 is irradiated with the electron beam 200. For example, rectangular multiple beams (a plurality of electron beams) 20 are formed by letting portions of the electron beam 200 applied to the positions of the plurality of holes 22 individually pass through a corresponding one of the plurality of holes 22 in the shaping aperture array substrate 203. The multiple beams 20 individually pass through corresponding blankers of the blanking aperture array mechanism 204. The blanker provides blanking control such that a corresponding beam individually passing becomes in an ON condition during a set writing time (irradiation time).

The multiple beams 20 having passed through the blanking aperture array mechanism 204 are reduced by the reducing lens 205, and travel toward the hole in the center of the limiting aperture substrate 206. The electron beam which was deflected by the blanker of the blanking aperture array mechanism 204 deviates from the hole in the center of the limiting aperture substrate 206 and is blocked by the limiting aperture substrate 206. In contrast, the electron beam which was not deflected by the blanker of the blanking aperture array mechanism 204 passes through the hole in the center of the limiting aperture substrate 206 as shown in FIG. 1. Thus, the limiting aperture substrate 206 blocks each beam which was deflected to be in an OFF state by the blanker of the blanking aperture array mechanism 204. Then, each beam for one shot of the multiple beams 20 is formed by a beam which has been made during a period from becoming beam ON to becoming beam OFF and has passed through the limiting aperture substrate 206. The multiple beams 20 having passed through the limiting aperture substrate 206 are focused by the objective lens (electromagnetic lens) 207 so as to be a pattern image of a desired reduction ratio. Then, all of the multiple beams 20 having passed through the limiting aperture substrate 206 are collectively deflected in the same direction by the main deflector 208 and the sub deflector 209 in order to irradiate respective beam irradiation positions on the target object 101. For example, when the XY stage 105 is continuously moving, tracking control is performed by the main deflector 208 so that the beam irradiation position may follow the movement of the XY stage 105. Ideally, the multiple beams 20 irradiating at a time are aligned at the pitch obtained by multiplying the arrangement pitch of a plurality of holes 22 in the shaping aperture array substrate 203 by the desired reduction ratio described above.

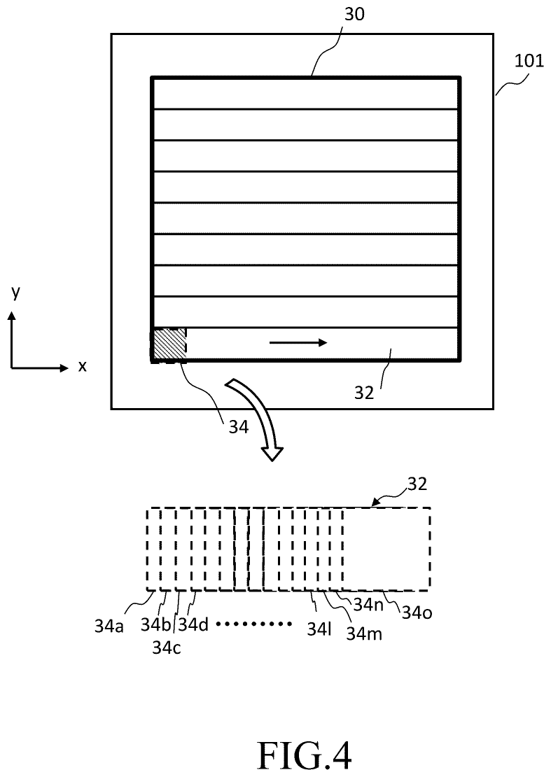

FIG. 4 is a conceptual diagram showing an example of writing operations according to the first embodiment. As shown in FIG. 4, a writing region 30 (bold line) of the target object 101 is virtually divided into a plurality of stripe regions 32 by a predetermined width in the y direction, for example. In the case of FIG. 4, the writing region 30 of the target object 101 is divided in the y direction, for example, into a plurality of stripe regions 32 by the width size being substantially the same as the design size of an irradiation region 34 (writing field) that can be irradiated with one irradiation of the multiple beams 20. The x-direction design size of the irradiation region 34 of the multiple beams 20 can be defined by (the number of x-direction beams)×(x-direction beam pitch). The y-direction size of the rectangular irradiation region 34 can be defined by (the number of y-direction beams)×(y-direction beam pitch).

First, the XY stage 105 is moved to make an adjustment such that the irradiation region 34 of the multiple beams 20 is located at the left end, or at a position further left than the left end, of the first stripe region 32, and then writing of the first stripe region 32 is performed. When writing the first stripe region 32, the XY stage 105 is moved, for example, in the −x direction, so that the writing may proceed relatively in the x direction. The XY stage 105 is moved, for example, continuously at a constant speed. After writing the first stripe region 32, the stage position is moved in the −y direction by the width of the stripe region 32.

Next, an adjustment is made such that the irradiation region 34 of the multiple beams 20 is located at the left end, or at a position further left than the left end, of the second stripe region 32. Then, writing of the second stripe region 32 is performed by moving the XY stage 105 in the −x direction, for example, to proceed the writing relatively in the x direction.

FIG. 4 shows the case where respective stripe regions 32 are written in the same direction, but, it is not limited thereto. For example, with respect to the stripe region 32 to be written following the stripe region 32 having been written in the x direction, it may be written in the −x direction by moving the XY stage 105 in the x direction, for example. Thus, due to performing writing while alternately changing the writing direction, the stage moving time can be reduced, which results in reducing the writing time. Owing to one shot of multiple beams 20 having been formed by individually passing through the holes 22 in the shaping aperture array substrate 203, a plurality of shot patterns up to the number of the holes 22 are maximally formed at a time.

Although FIG. 4 shows the case where the stage moving for writing each stripe region is performed once for each writing, it is not limited thereto. It is also preferable to perform multiple writing (multiple pass writing) such that the stage moves on the same position a plurality of times. In that case, preferably, the multiple writing is performed while shifting the position in the y direction by 1/n of the width of the stripe region. Alternatively, it is also preferable to perform multiple writing (multiple writing in a pass) that writes the same position plural times by different beams during one stage movement.

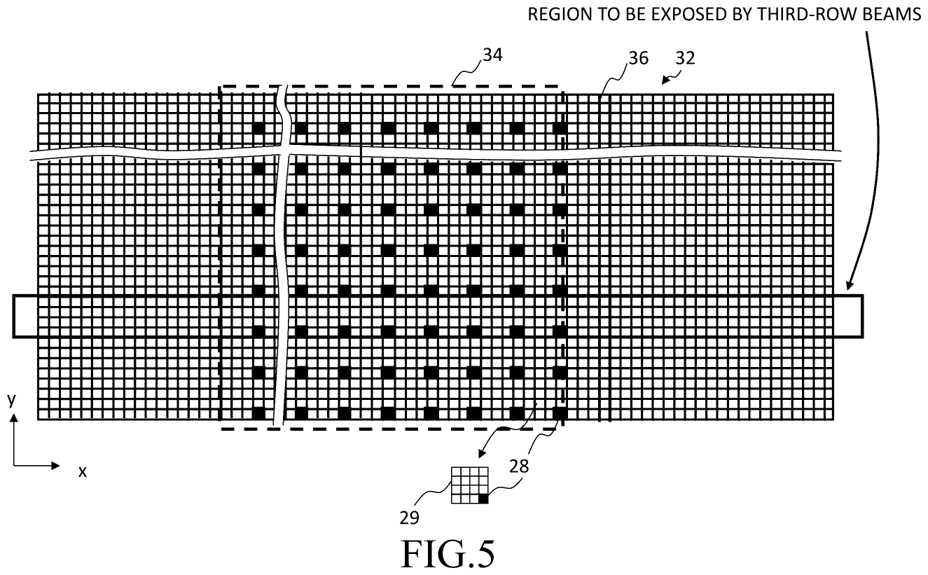

FIG. 5 is an illustration showing an example of an irradiation region of multiple beams and a pixel to be written (writing target pixel) according to the first embodiment. In FIG. 5, the stripe region 32 is divided into a plurality of mesh regions by the beam size of each of the multiple beams 20, for example. Each mesh region serves as a writing target pixel 36 (unit region of beam irradiation, irradiation position). The size of the writing target pixel 36 is not limited to the beam size, and may be any size regardless of beam size. For example, it may be 1/n (n being an integer of 1 or more) of the beam size. FIG. 5 shows the case where the writing region on the target object 101 is divided, for example, in the y direction, into a plurality of stripe regions 32 by the width size being substantially the same as the size of the irradiation region 34 (writing field) that can be irradiated with one irradiation of the multiple beams 20. The x-direction size of the rectangular, including square, irradiation region 34 can be defined by (the number of x-direction beams)×(x-direction beam pitch). The y-direction size of the rectangular irradiation region 34 can be defined by (the number of y-direction beams)×(y-direction beam pitch). FIG. 5 shows the case of multiple beams of 512×512 (rows×columns) having been simplified to 8×8 (rows×columns). In the irradiation region 34, there are shown a plurality of pixels 28 (beam writing positions) which can be irradiated with one shot of the multiple beams 20. The pitch between adjacent pixels 28 is the beam pitch of the multiple beams. A sub-irradiation region 29 (pitch cell region) is configured by a rectangular, including square, region surrounded by the size of beam pitches in the x and y directions. In the example of FIG. 5, each sub-irradiation region 29 is composed of 4×4 pixels, for example.

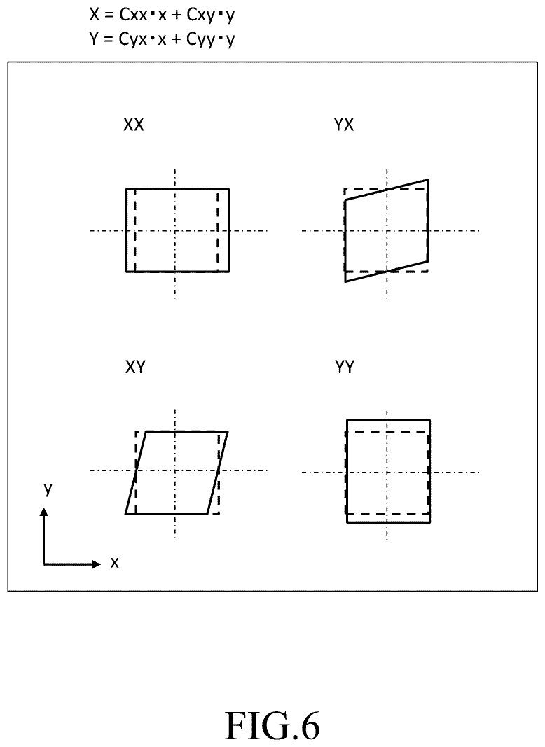

FIG. 6 is an illustration showing a parameter of a linear component according to the first embodiment. In FIG. 6, a design rectangular beam array shape is depicted by a dotted line. FIG. 6 shows the case where the origin of the x and y directions is the center of the rectangular beam array shape. The XX linear component indicates a displacement component which deviates in the x direction in proportion to the design coordinate in the x direction. Specifically, the XX linear component indicates an x-direction displacement component which expands (or contracts) in the x direction with respect to the design beam array shape. The YY linear component indicates a displacement component which deviates in the y direction in proportion to the design coordinate in the y direction. Specifically, the YY linear component indicates a y-direction displacement component which expands (or contracts) in the y direction with respect to the design beam array shape. The XY linear component indicates a displacement component which deviates in the x direction in proportion to the design coordinate in the y direction. Specifically, the XY linear component indicates an oblique displacement component which deviates in the x direction while maintaining the y direction with respect to the design beam array shape. The YX linear component indicates a displacement component which deviates in the y direction in proportion to the design coordinate in the x direction. Specifically, the YX linear component indicates an oblique displacement component which deviates in the y direction while maintaining the x direction with respect to the design beam array shape. C_{XX} indicates a linear component parameter (linear (first order) approximation coefficient) depending on a displacement amount which deviates in the x direction in proportion to the design coordinate in the x direction. C_{YY} indicates a linear component parameter depending on a displacement amount which deviates in the y direction in proportion to the design coordinate in the y direction. C_{XY} indicates a linear component parameter depending on a displacement amount which deviates in the x direction in proportion to the design coordinate in the y direction. C_{YX} indicates a linear component parameter depending on a displacement amount which deviates in the y direction in proportion to the design coordinate in the x direction.

The x-coordinate displacement amount X of each point in the beam array shape whose origin is the beam array center can be approximated by the following equation (1-1) using design coordinates (x, y) whose origin is the beam array center. Similarly, the y-coordinate displacement amount Y of each point in the beam array shape whose origin is the beam array center can be approximated by the following equation (1-2) using design coordinates (x, y) whose origin is the beam array center.

$$X = {C}_{XX} \cdot x + {C}_{XY} \cdot y \qquad ( 1 - 1 )$$

$$Y = {C}_{YX} \cdot x + {C}_{YY} \cdot y \qquad ( 1 - 2 )$$

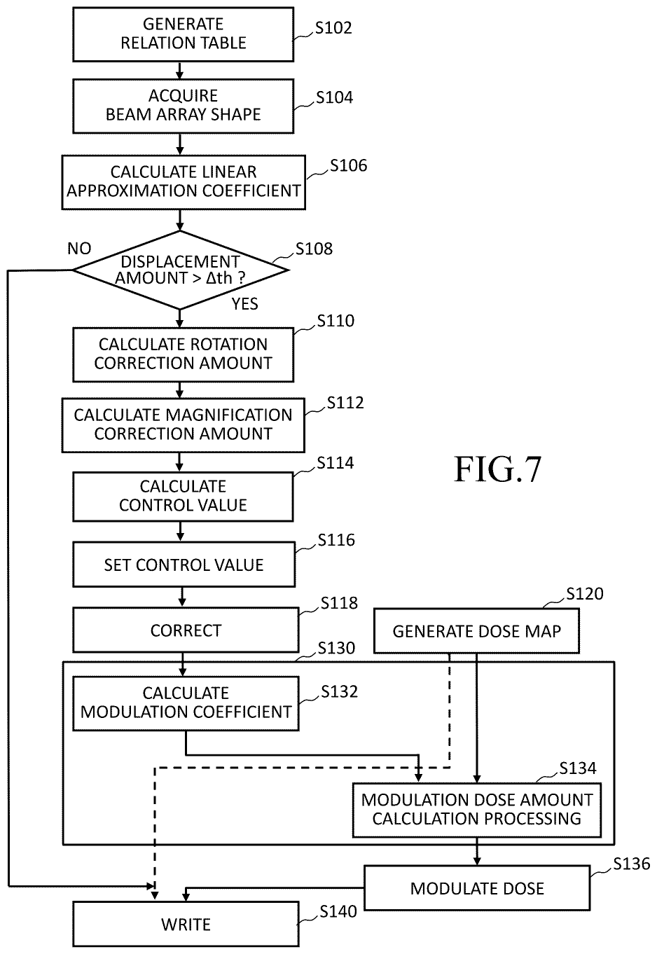

FIG. 7 is a flowchart showing an example of main steps of a writing method according to the first embodiment. In FIG. 7, the writing method of the first embodiment executes a series of steps: a relation table generation step (S102), a beam array shape acquisition step (S104), a linear approximation coefficient calculation step (S106), a determination step (S108), a rotation correction amount calculation step (S110), a magnification correction amount calculation step (S112), a control value calculation step (S114), a control value setting step (S116), a correction step (S118), a dose map generation step (S120), a modulation dose amount calculation step (S130), a dose modulation step (S136), and a writing step (S140). The modulation dose amount calculation step (S130) executes, as internal steps, a modulation coefficient calculation step (S132) and a modulation dose amount calculation processing step (S134).

In the relation table generation step (S102), a relation table is generated in which all of a rotation amount θ and a magnification m of the beam array shape described later, and a voltage V1 of the electrostatic lens 212, a voltage V2 of the electrostatic lens 214, and a voltage V3 of the electrostatic lens 216 for making the focus position be located on the substrate surface are set to be variable. Data for generating the relation table can be acquired by experiment, simulation, or the like. By applying the multiple beams 20, condition matrices for the voltages V1, V2, and V3 are generated, for example. Then, a rotation amount θ, a magnification m, and a focus position under each condition are measured. Based on the measurement results, a group of V1, V2, and V3 which makes the rotation amount be θ and the magnification be m is obtained under the condition that the focus position is located at a desired position.

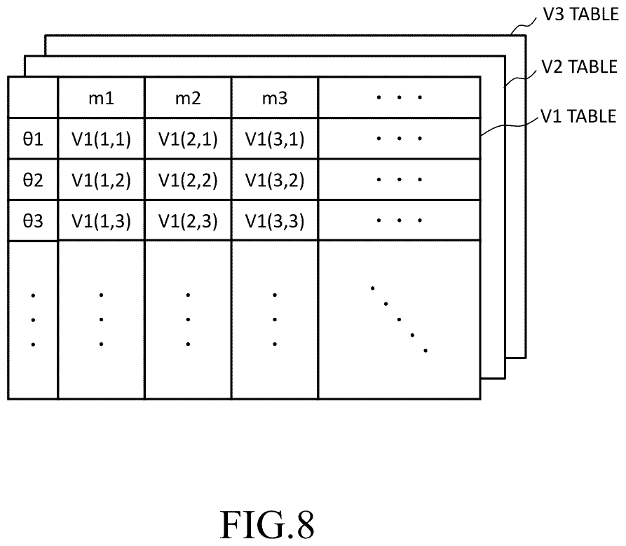

FIG. 8 is an illustration showing an example of a relation table according to the first embodiment. FIG. 8 shows a V1 table for the electrostatic lens 212, a V2 table for the electrostatic lens 214, and a V3 table for the electrostatic lens 216. In each table, the ordinate axis represents rotation amounts θ1, θ2 and . . . , and the abscissa axis represents magnifications m1, m2, and . . . . Each table defines the voltage V1 (V2 or V3) for giving a desired rotation amount θ and magnification m. The generated relation table is stored in the storage device 144. The relation table may be generated in the writing apparatus 100, and stored in the storage device 144, or may be generated off-line, input to the writing apparatus 100, and stored in the storage device 144.

In the beam array shape acquisition step (S104), first, a plurality of positions in a beam array are measured using the mark 106. Specifically, for example, in the case of using a reflection type mark, a beam or a plurality of adjacent beams scans the mark 106 in order to obtain a secondary electron image by detecting secondary electrons reflected from the mark 106 by the detector 107. Then, based on the secondary electron image, the position of the applied beam (or the plurality of beams) is measured. For example, positions of 5×5 beams in a beam array, including beams at the four corners of the beam array, are measured. Selection of a beam or a plurality of beams can be performed by the blanking aperture array mechanism 204. As the position of a plurality of beams, for example, the center position of the plurality of beams can be measured. Alternatively, the position of each of a plurality of beams is measured to obtain an average as the position of the plurality of beams. The amount obtained by subtracting the average of positional deviations of respective positions from a measured result of each position is defined as a positional deviation amount deviated from the design position of each beam. Alternatively, a positional deviation amount of each beam may be acquired from a positional deviation distribution based on the beam array shape obtained from the writing result.

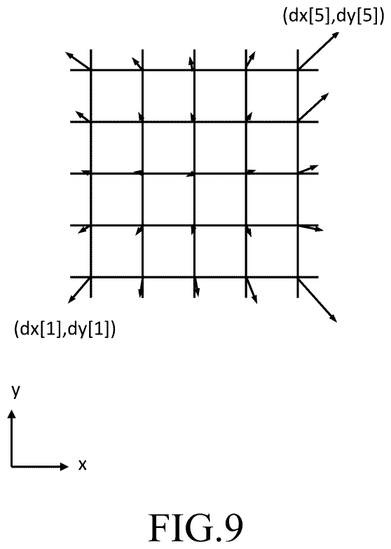

FIG. 9 is an illustration showing an example of a beam position according to the first embodiment. FIG. 9 shows a positional deviation amount from the design position of a beam (or a plurality of beams). 5×5 beam positions are shown in the example of FIG. 9.

In the linear approximation coefficient calculation step (S106), the beam array shape acquisition unit 50 calculates linear component parameters (linear approximation coefficients) C_{XX}, C_{XY}, C_{YX}, and C_{YY} by approximating positional deviations dx(i) and dy(i) of a plurality of positions by using the equations (1-1) and (1-2) described above.

In the determination step (S108), the determination unit 51 determines whether each value of C_{YX} and C_{XX} in calculated linear component parameters is larger than a threshold Δth. If not larger, it is determined there is no need for correction, and it proceeds to the writing step (S120). If larger, it proceeds to the rotation correction amount calculation step (S110).

In the rotation correction amount calculation step (S110), the rotation correction amount calculation unit 52 calculates a rotation correction amount Δθ of an acquired beam array shape by using a linear component parameter C_{YX} (the second coefficient) indicating a displacement component which deviates in the y direction (the second direction) in proportion to the design coordinate in the x direction (the first direction) of the acquired beam array shape. The rotation correction amount Δθ can be defined by the following equation (2).

$$Δ θ = {tan}^{- 1} ( - {C}_{YX} ) \qquad ( 2 )$$

In the first embodiment, for example, the x direction (the first direction) is parallel to the writing direction in the case of writing each stripe region of a plurality of stripe regions 32 obtained by dividing the region 30 of the target object 101 into stripes. For example, the y direction (the second direction) is orthogonal to the x direction.

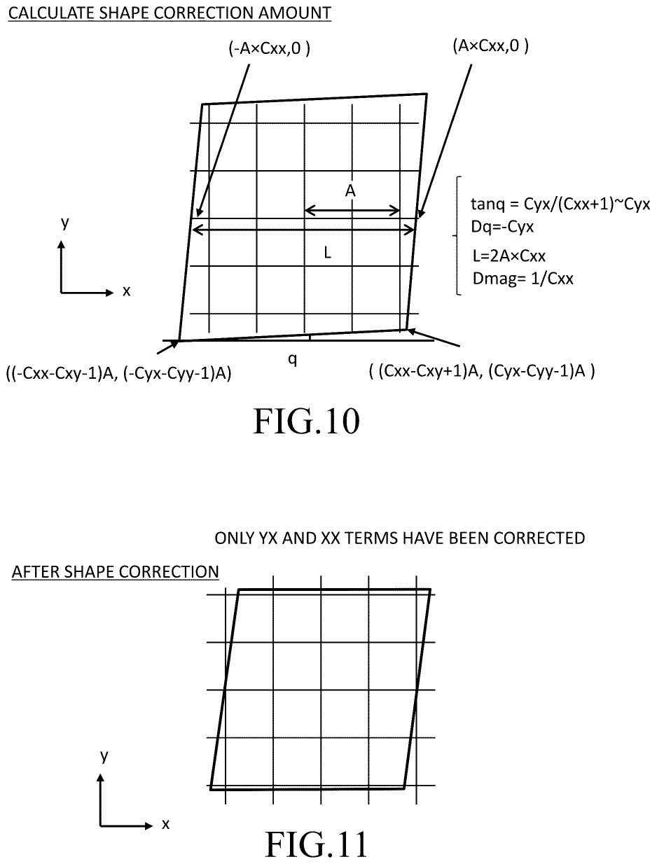

FIG. 10 is an illustration for explaining a rotation amount θ and a magnification m of a beam array shape according to the first embodiment. In FIG. 10, the coordinates of the lower right corner of a beam array can be defined by ((C_{XX}−C_{XY}+1)A, (C_{YX}−C_{YY}−1)A). The coordinates of the lower left corner can be defined by ((−C_{XX}−C_{XY}−1)A, (−C_{YX}−C_{YY}−1)A). Assuming that the rotation angle is gradient θ from the x axis, tan θ can be defined by the following equation (3).

$$tan θ = {C}_{YX} / ( {C}_{XX} + 1 ) \approx {C}_{YX} \qquad ( 3 )$$

C_{XX} is sufficiently small. Therefore, it can be approximated (defined) to be tan θ≈C_{YX}. For correcting rotation, a reverse direction rotation is performed as shown in the equation (4).

$$tan ( - θ ) = - {C}_{YX} / ( {C}_{XX} + 1 ) \approx - {C}_{YX} \qquad ( 4 )$$

Since the rotation correction amount is Δθ=−θ, it can be defined by the equation (2).

In the magnification correction amount calculation step (S112), the magnification correction amount calculation unit 54 calculates a magnification correction amount Δm of an acquired beam array shape by using a linear component parameter C_{XX} (the first coefficient) indicating a displacement component which deviates in the x direction in proportion to the design coordinate in the x direction (the first direction) of the acquired beam array shape, where the x direction (the first direction) is parallel to the direction of writing performed while continuously moving the XY stage 105 with the target object 101 thereon. The magnification correction amount Δm can be defined by the following equation (5).

$$Δ m = 1 / {C}_{XX} \qquad ( 5 )$$

In FIG. 10, assuming that the x direction dimension from the center position of the design beam array is A, coordinates of the end of the x direction dimension passing through the center position of the acquired beam array can be defined by (A·C_{XX}, 0). Coordinates of the end of the −x direction dimension passing through the center position of the acquired beam array can be defined by (−A·C_{XX}, 0). Therefore, the y direction dimension L passing through the center position of a measured beam array can be defined by the following equation (6).

$$L = 2 A \cdot {C}_{XX} \qquad ( 6 )$$

Thus, since the magnification of the acquired beam array can be defined to be L/2A when regarding the magnification of the design beam array as 1, it is possible to define the magnification by using C_{XX}. The magnification correction amount Δm should be a reciprocal of the magnification of the acquired beam array. Therefore, the magnification correction amount Δm can be defined by the following equation (5).

In the control value calculation step (S114), the control value calculation unit 56 reads the rotation angle θ and magnification m, which are under the current control, from the storage device 144, and calculates the optimum rotation angle based on θ′=θ+Δθ and magnification based on m′=m+Δm in order to correct the beam array shape. Furthermore, the control value calculation unit 56 reads the relation table stored in the storage device 144, and calculates, referring to the relation table, voltages V1, V2, and V3 of the electrostatic lenses 212, 214, and 216 corresponding to the calculated rotation amount θ′ and magnification m′.

In the control value setting step (S116), the control value setting unit 58 outputs the calculated voltages V1, V2, and V3 to the electrostatic lens control circuit 131. The electrostatic lens control circuit 131 sets the voltage V1 as a control voltage for the electrostatic lens 212, the voltage V2 as a control voltage for the electrostatic lens 214, and the voltage V3 as a control voltage for the electrostatic lens 216.

In the correction step (S118), two or more electrostatic lenses 212 and 214 perform at least one of rotation correction corresponding to a rotation correction amount of the beam array shape, and magnification correction corresponding to a magnification correction amount of the beam array shape. Here, the case of performing both the corrections is described below.

FIG. 11 is an illustration showing an example of a state where rotation correction and magnification correction of a beam array have been performed according to the first embodiment. As a result of performing magnification adjustment in the x direction, as shown in FIG. 11, the x-direction dimension passing through the center position of the beam array can be coincident with the design dimension. Furthermore, as a result of performing rotation adjustment, as shown in FIG. 11, the displacement component which deviates in the y direction in proportion to the design coordinate in the x direction can be corrected.

The focus position of the multiple beams 20 is adjusted using another electrostatic lens 216 being different from the two or more electrostatic lenses 212 and 214. Although the case of adjusting the focus position has here been described, it is also preferable to adjust a crossover position. For example, the final crossover position is adjusted.

In the first embodiment, since the beam array shape is corrected using the electrostatic lenses 212 and 214 where no hysteresis occurs, the reproducibility is sufficient enough to omit the operation of confirming the shape.

As shown in FIG. 11, there still remain the displacement component (YY term component) which deviates in the y direction in proportion to the design coordinate in the y direction, and the displacement component (XY term component) which deviates in the x direction in proportion to the design coordinate in the y direction. According to the first embodiment, displacement amounts of the YY term component and the XY term component are reduced by performing dose modulation.

In the dose map generation step (S120), the writing data processing unit 70 reads chip pattern data (writing data) from the storage device 140, and performs rasterization processing. Specifically, a pattern density (pattern area density) is calculated for each pixel 36.

Next, the writing data processing unit 70 calculates, for each proximity mesh region, a proximity effect correction dose Dp(x) for correcting a proximity effect. An unknown proximity effect correction dose Dp(x) can be defined by a threshold value model for proximity effect correction, which is the same as the one used in a conventional method, where a backscatter coefficient η, a dose threshold value Dth of a threshold value model, a pattern area density ρ″, and a distribution function g(x) are used. The proximity effect correction dose Dp(x) is obtained as a relative value standardized by defining the base dose D_{base} to be 1.

Next, the writing data processing unit 70 calculates, for each pixel, an incident dose D(x) (dose amount) with which the pixel concerned is irradiated. The incident dose D(x) can be calculated, for example, by multiplying a base dose D_{base} by a proximity effect correction dose Dp and a pattern area density ρ′. The base dose D_{base} can be defined by Dth/(½+η), for example. Thereby, it is possible to obtain an incident dose D(x) for each pixel, for which a proximity effect has been corrected, based on a layout of a plurality of figure patterns defined by the writing data. Alternatively, it is also preferable that the writing data processing unit 70 defines an incident dose D(x) for each pixel by using an incident dose D(x) standardized regarding the base dose D_{base} as 1. In that case, for example, the incident dose D(x) can be calculated by multiplying the proximity effect correction dose Dp by the pattern area density ρ′.

Next, the writing data processing unit 70 generates a dose map whose element is an incident dose D(x) of each pixel 36. That is, each pixel (position) (x, y) and its incident dose D(x) are relatedly defined. The generated dose map is stored in the storage device 142. The writing data processing unit 70 generates a dose map with respect to the whole of the writing region 30 where writing processing is performed in accordance with the writing data (chip data).

In the case of performing multiple writing, a dose map is generated for each writing processing of each time of multiple writing.

In the modulation dose amount calculation step (S130), the modulation dose amount calculation unit 61 calculates a modulation dose amount for each pixel 36 (unit region) of a plurality of pixels 36 obtained by dividing a stripe region into mesh regions, based on at least one of a linear component parameter C_{YY} (the third coefficient) indicating a displacement component which deviates in the x direction (the first direction), for example, in proportion to the design coordinate in the y direction (the second direction), for example, of an acquired beam array shape, and a linear component parameter C_{XY} (the fourth coefficient) indicating a displacement component which deviates in the y direction (the second direction), for example, in proportion to the design coordinate in the y direction (the second direction), for example, of the acquired beam array shape. Specifically, it operates as follows:

In the modulation coefficient calculation step (S132), the modulation coefficient calculation unit 60 calculates a modulation coefficient Δ_{YY} (the first modulation coefficient) for each pixel 36 (unit region) of a plurality of pixels 36 obtained by dividing the stripe region 32 into mesh regions, by using a linear component parameter C_{YY} (the third coefficient) indicating a displacement component which deviates in the y direction of an acquired beam array shape in proportion to the design coordinate in the y direction of the acquired beam array shape.

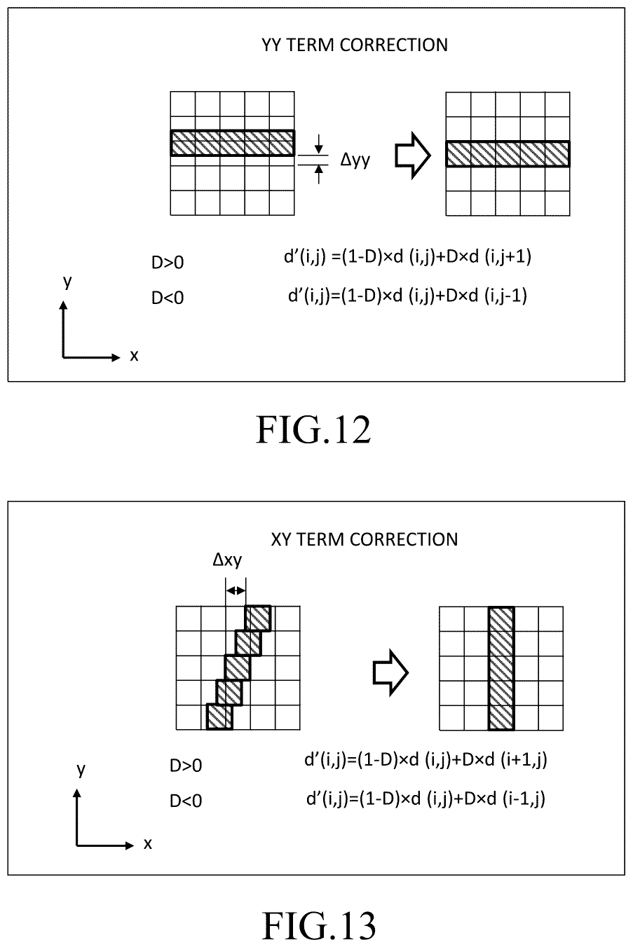

FIG. 12 is an illustration explaining a method for correcting a YY term component according to the first embodiment. In FIG. 12, the rate of displacement in the y direction of the irradiation position of each beam of the multiple beams 20 from the pixel 36 is calculated as a modulation coefficient Δ_{YY}. For example, if defining the y-direction size of the pixel 36 to be 1, the length deviated in the y direction is equivalent to a modulation coefficient Δ_{YY}. In the case where the center of the design beam array is defined as the origin, since the YY term component changes depending on the position in the y direction, the modulation coefficient Δ_{YY} also changes depending on the position in the y direction from the center of a beam array. Therefore, the modulation coefficient Δ_{YY} is calculated for each y position of each pixel on the surface of the target object 101. As shown in FIG. 4, for example, when the y-direction width of the stripe region 32 is the same as the y-direction size of the beam array region, the modulation coefficient Δ_{YY} is calculated for each y position of each pixel while defining the y-direction center of each stripe region 32 as the origin in the y direction. As long as the same y-coordinate, since the YY term component remains the same even if deviation occurs in the x direction, the modulation coefficient Δ_{YY} also keeps the same value. Furthermore, in respective stripe regions 32, since the modulation coefficients Δ_{YY} at the same positions are the same values, if the modulation coefficients Δ_{YY} is calculated for a pixel in one stripe region 32, the calculation result can be used for a pixel in each of other stripe regions 32.

Next, the modulation coefficient calculation unit 62 calculates a modulation coefficient Δ_{XY} (the second modulation coefficient) for each pixel 36 by using a linear component parameter C_{XY} (the fourth coefficient) indicating a displacement component which deviates in the x direction of an acquired beam array shape in proportion to the design coordinate in the y direction of the acquired beam array shape.

FIG. 13 is an illustration explaining a method for correcting an XY term component according to the first embodiment. In FIG. 13, the rate of displacement in the x direction of the irradiation position of each beam of the multiple beams 20 from the pixel 36 is calculated as a modulation coefficient Δ_{XY}. For example, if defining the x-direction size of the pixel 36 to be 1, the length deviated in the x direction is equivalent to a modulation coefficient Δ_{XY}. In the case where the center of the design beam array is defined as the origin, since the XY term component changes depending on the position in the y direction, the modulation coefficient Δ_{XY} also changes depending on the position in the y direction from the center of a beam array. Therefore, the modulation coefficient Δ_{XY} is calculated for each y position of each pixel on the surface of the target object 101. Similarly to the case described above, for example, when the y-direction width of the stripe region 32 is the same as the y-direction size of the beam array region, the modulation coefficient Δ_{XY} is calculated for each y position of each pixel while defining the y-direction center of each stripe region 32 as the origin in the y direction. As long as the same y-coordinate, since the XY term component remains the same even if deviation occurs in the x direction, the modulation coefficient Δ_{XY} also keeps the same value. Furthermore, in respective stripe regions 32, since the modulation coefficients Δ_{XY} at the same positions are the same values, if the modulation coefficients Δ_{XY} is calculated for a pixel in one stripe region 32, the calculation result can be used for a pixel in each of other stripe regions 32.

In the modulation dose amount calculation processing step (S134), the modulation dose amount calculation processing unit 63 calculates a modulation dose amount for each pixel 36 by using at least one of the incident dose D(x) for each pixel 36, the modulation coefficient Δ_{YY} and the modulation coefficient Δ_{XY}.

First, a dose modulation is performed for correcting a YY term component. As shown in FIG. 12, using a dose amount d(i,j) of each pixel defined in the dose map, a modulation dose amount d′ (i,j) which serves as a dose amount after modulating the target pixel (i,j) is calculated for correcting a YY term component. In the case of defining the x and y coordinates regarding the design beam array center as the origin, the modulation dose amount d′ (i,j) can be defined when Δ_{YY}>0 by the following equation (7-1). When Δ_{YY}<0, the modulation dose amount d′ (i,j) can be defined by the following equation (7-2).

$${d}^{′} ( i , j ) = ( 1 - {Δ}_{YY} ) d ( i , j ) + {Δ}_{YY} d ( i , j + 1 ) \qquad ( 7 - 1 )$$

$${d}^{′} ( i , j ) = ( 1 - {Δ}_{YY} ) d ( i , j ) + {Δ}_{YY} d ( i , j - 1 ) \qquad ( 7 - 2 )$$

Next, a dose modulation is performed for correcting an XY term component. As shown in FIG. 13, using a dose amount d(i,j) of each pixel after correcting the YY term component, a modulation dose amount d′ (i,j) which serves as a dose amount after modulating the target pixel (i,j) is calculated for correcting an XY term component. In the case of defining the x and y coordinates regarding the design beam array center as the origin, the modulation dose amount d′ (i,j) can be defined when Δ_{XY}>0 by the following equation (8-1). When Δ_{XY}<0, the modulation dose amount d′ (i,j) can be defined by the following equation (8-2).

$${d}^{′} ( i , j ) = ( 1 - {Δ}_{XY} ) d ( i , j ) + {Δ}_{XY} d ( i + 1 , j ) \qquad ( 8 - 1 )$$

$${d}^{′} ( i , j ) = ( 1 - {Δ}_{XY} ) d ( i , j ) + {Δ}_{XY} d ( i - 1 , j ) \qquad ( 8 - 2 )$$

According to the first embodiment, using two or more objective lenses, at least one of rotation correction corresponding to a rotation correction amount of the beam array shape, and magnification correction corresponding to a magnification correction amount of the beam array shape is performed, and a dose amount is modulated for each pixel by using a modulation dose amount. It is specifically described below.

In the dose modulation step (S136), the dose modulation unit 64 modulates a dose amount for each pixel, using a modulation dose amount d′ (i,j). Specifically, the modulation dose amount d′ (i,j) serving as a dose amount after modulation is substituted for the dose amount d(i,j) before modulation.

Using the dose amount of each pixel after modulation, the writing data processing unit 70 generates a modulation dose map, and stores it in the storage device 142.

In the writing step (S140), first, the writing data processing unit 70 calculates an irradiation time for each pixel 36 by using a dose D(x) (dose amount) after modulation defined in the modulation dose map. The irradiation time for each pixel 36 can be calculated by dividing the dose D(x) of the pixel concerned by a current density J. In the case where the dose D(x) defined in the modulation dose map is standardized regarding the base dose D_{base} as 1, the irradiation time for each pixel 36 can be calculated by dividing, by the current density J, the value obtained by multiplying the dose D(x) by the base dose D_{base}.

The writing data processing unit 70 rearranges obtained irradiation time data for each pixel 36 in the order of shot, and stores it in the storage device 142. The transmission processing unit 74 transmits the irradiation time data to the deflection control circuit 130 in the order of shot.

Under the control of the writing control unit 72, the writing mechanism 150 writes a pattern on the target object 101 with the multiple beams 20 for which modulation of the dose amount and at least one of rotation correction of the beam array shape and magnification correction of the beam array shape have been performed. Here, a pattern is written on the target object 101 with the multiple beams 20 for which modulation of the dose amount and both of rotation correction of the beam array shape and magnification correction of the beam array shape have been performed. The writing mechanism 150 writes a pattern on the target object 101 while continuously moving in the x direction relatively.

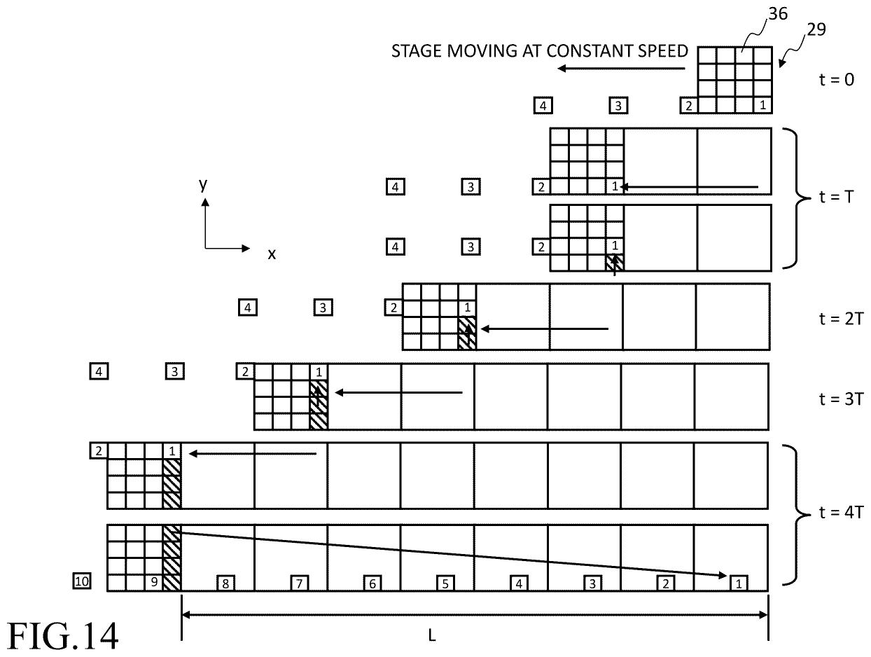

FIG. 14 is an illustration for explaining an example of a multiple beam writing operation according to the first embodiment. FIG. 14 shows the case where the inside of each sub-irradiation region 29, which includes the beam irradiation position of one beam of the multiple beams 20 and is surrounded by the beam pitch (pitch between beams), is written with four different beams. The example of FIG. 14 shows a writing operation where the XY stage 105 continuously moves at the speed at which it moves the distance L of eight beam pitches during writing a ¼ region, namely the region of 1/(the number of beams used for irradiation), in each sub-irradiation region 29. FIG. 14 shows the case where each sub-irradiation region 29 is composed of 4×4 pixels, for example. In the writing operation shown in FIG. 14, for example, while the XY stage 105 moves the distance L of eight beam pitches, four different pixels 36 in the same sub-irradiation region 29 are written (exposed) by applying four shots of the multiple beams 20 at a shot cycle T with sequentially shifting the irradiation position (pixel 36) by the sub deflector 209. In order that the relative position between the irradiation region 34 and the target object 101 may not deviate by the movement of the XY stage 105 while the four pixels 36 are written (exposed), the irradiation region 34 is made to follow the movement of the XY stage 105 by collective deflection of all of the multiple beams 20 by the main deflector 208. In other words, a tracking control is performed. After one tracking cycle is completed, tracking is reset to return to the previous (last) tracking start position. Since writing of the pixels in the first column from the right of each sub-irradiation region 29 has been completed, in the next tracking cycle after resetting the tracking, first, the sub deflector 209 provides deflection such that the writing position of a beam is adjusted (shifted) to write the second pixel column from the right still not having been written in each sub-irradiation region 29, for example. By repeating this operation during writing the stripe region 32, as shown in the lower part of FIG. 4, the position of the irradiation region 34 (34a to 34o) of the multiple beams 20 is sequentially moved (shifted) to perform writing.

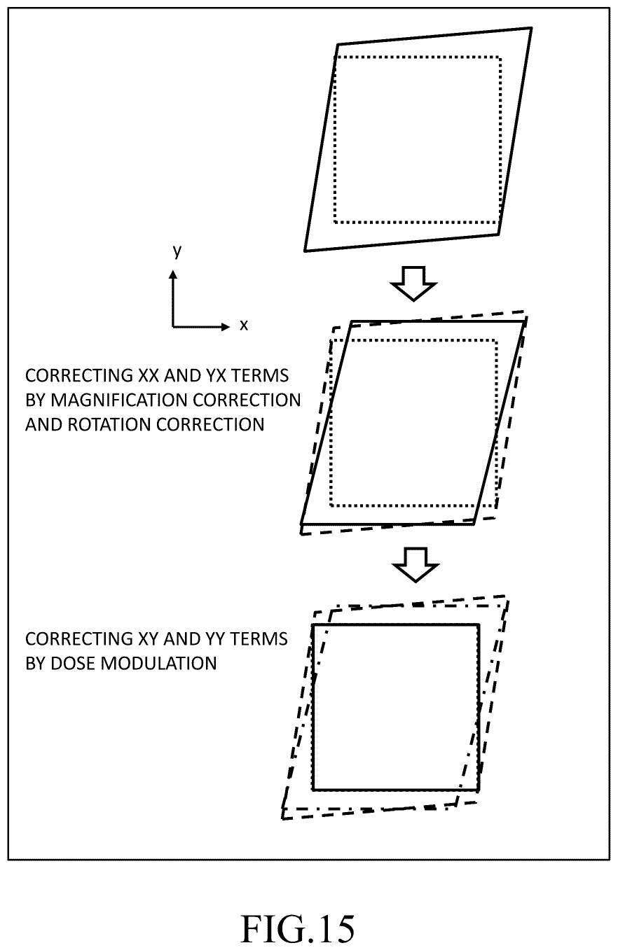

FIG. 15 is an illustration showing an example of a position deviation state in the case of writing according to the first embodiment. As described above, the beam array shape can be corrected by rotation correction and magnification correction to the state shown in the middle of FIG. 15 from the one shown in the upper part of FIG. 15. A dose distribution equivalent to the dose distribution which is acquired when the beam array shape has been corrected by dose modulation to be the state shown in the lower part of FIG. 15 can be obtained by writing by using the beam array shape shown in the middle of FIG. 15 and the dose modulation described above.

In the examples described above, the XY term component increases by performing rotation correction for correcting the YX term component. In also the case of correcting the XY term component by dose modulation, it is desirable that the displacement amount is not too large. Then, as a modified example of the first embodiment, it is also preferable to set the upper limit Δθₘₐₓ for the rotation correction amount Δθ. Therefore, if the value calculated by the equation (2) exceeds the upper limit Δθₘₐₓ, the rotation correction amount Δθ should be limited to Δθₘₐₓ, and defined by the following equation (9).

Δθ=Δθₘₐₓ (9)

In that case, correction of the YX term component becomes imperfect. However, by writing continuously moving in the x direction, as shown in FIG. 4, the irradiation regions 34 (34a to 34o) of the multiple beams 20 for each tracking reset overlap each other with shifting positions in the x direction. Therefore, positional deviation of the YX term component is averaged by the shot of each tracking reset. Thereby, even in the case of setting an upper limit for the rotation correction amount Δθ, it is possible to make the beam array shape close in shape to the design beam array shape.

As described above, according to the first embodiment, positional deviation due to displacement of a linear component of a beam array shape in multiple beam writing can be reduced.

### Second Embodiment

The above first embodiment describes the case where rotation correction and magnification correction are performed using the electrostatic lenses 212 and 214 serving as two or more objective lenses, but it is not limited thereto. A second embodiment describes the case where an air-core coil being an electromagnetic lens is used, instead of the electrostatic lens, for rotation correction. The electromagnetic lens is not limited to the air-core coil, and the one with smaller hysteresis is desirable.

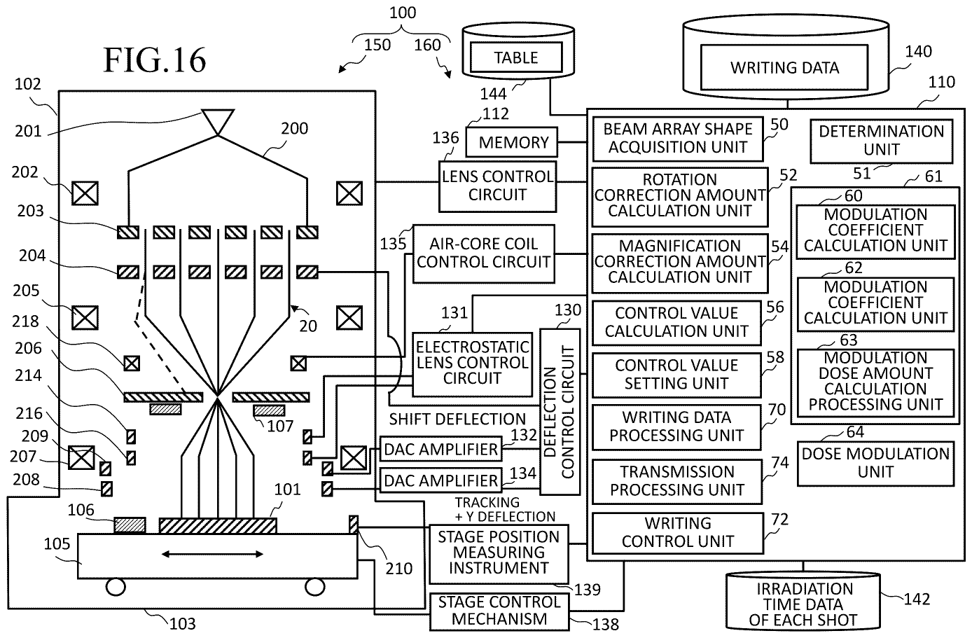

FIG. 16 is a conceptual diagram showing a configuration of a writing apparatus according to the second embodiment. FIG. 16 is the same as FIG. 1 except that an air-core coil control circuit 135 is arranged, and an air-core coil 218 is arranged instead of the electrostatic lens 212. Although FIG. 16 shows the case where the air-core coil 218 is disposed between the reducing lens 205 and the limiting aperture substrate 206, it is not limited thereto. It is acceptable as long as the air-core coil 218 is disposed between the blanking aperture array mechanism 204 and the target object 101.

The air-core coil 218 is controlled by the air-core coil control circuit 135. The main steps of the writing method according to the second embodiment are the same as those of FIG. 7. The contents of the second embodiment may be the same as those of the first embodiment except for what is particularly described below.

In the relation table generation step (S102), a relation table is generated in the case where the beam array shape is rotated by a rotation amount θ, the magnification is set at m, and each of the excitation current I1 of the air-core coil 218 for letting the focus position be on the substrate surface, the voltage V2 of the electrostatic lens 214, the voltage V3 of the electrostatic lens 216, the rotation amount θ, and the magnification m is set variably. Data for generating the relation table can be acquired by experiment, simulation, or the like. For example, by applying the multiple beams 20, first, the beam array shape is rotated using the air-core coil 218 by the rotation amount θ. In that state, the beam array shape is enlarged or reduced to the magnification m, using the electrostatic lens 214. By this, since the focus position deviates from the surface of the target object 101, the electrostatic lens 216 adjusts the focus position to be on the surface of the target object 101. Specifically describing, the magnification and focus of an image deviate due to rotation adjustment of the image. The focus and rotation angle of an image deviate due to magnification adjustment of the image, and the rotation angle and magnification of an image deviate due to focus adjustment of the image. Therefore, by repeating the adjustment a plurality of times, the excitation current I1 and the voltages V2 and V3 are searched for making deviations of the three parameters of the rotation, magnification, and focus position smaller than respective acceptable ranges. By variably setting each of the rotation amount θ and the magnification m, adjustment is performed similarly.

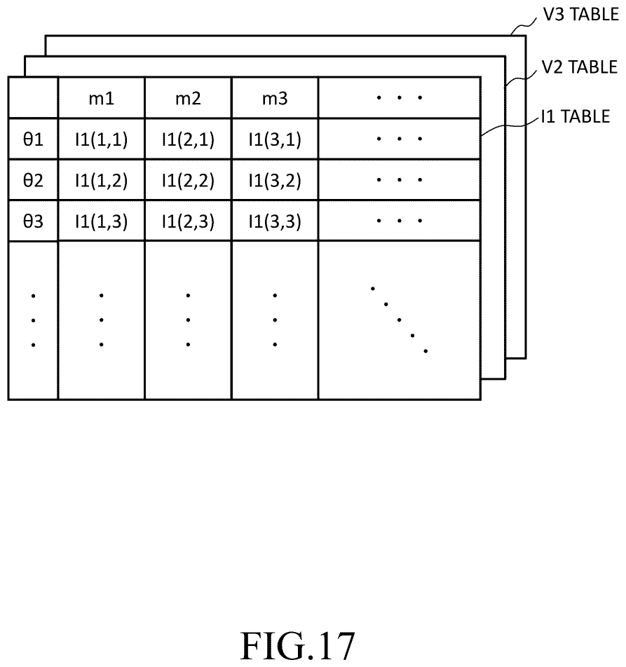

FIG. 17 is an illustration showing an example of a relation table according to the second embodiment. FIG. 17 shows an excitation current I1 table for the air-core coil 218, a V2 table for the electrostatic lens 214, and a V3 table for the electrostatic lens 216. In each table, the ordinate axis represents rotation amounts θ1, θ2, and . . . , and the abscissa axis represents magnifications m1, m2, and . . . . The excitation current I1 (the voltage V2 or V3) for having a desired rotation amount θ and magnification m is defined. The generated relation table is stored in the storage device 144. The relation table may be generated in the writing apparatus 100, and stored in the storage device 144. Alternatively, it may be generated off-line, input to the writing apparatus 100, and stored in the storage device 144.

The contents of the beam array shape acquisition step (S104), the linear approximation coefficient calculation step (S106), the determination step (S108), the rotation correction amount calculation step (S110), and the magnification correction amount calculation step (S112) are the same as those of the first embodiment.

In the control value calculation step (S114), the control value calculation unit 56 reads a present rotation amount θ, magnification m, and relation table stored in the storage device 144, and calculates an excitation current I1 of the air-core coil 218, voltages V2 and V3 of the electrostatic lenses 214 and 216 which are corresponding to the rotation amount θ and magnification m calculated in reference to the relation table.

In the control value setting step (S116), the control value setting unit 58 outputs a calculated excitation current I1 to the air-core coil control circuit 135. The air-core coil control circuit 135 sets the excitation current I1 as an excitation current for the air-core coil 218. The control value setting unit 58 outputs calculated voltages V2 and V3 to the electrostatic lens control circuit 131. The electrostatic lens control circuit 131 sets the voltage V2 as a control voltage for the electrostatic lens 214, and the voltage V3 as a control voltage for the electrostatic lens 216.

In the correction step (S118), the combination of the electrostatic lens 214 and the air-core coil 218 performs rotation correction of the beam array shape corresponding to a rotation correction amount, and magnification correction of the beam array shape corresponding to a magnification correction amount. The rotation correction is executed by the air-core coil 218 in the combination of the electrostatic lens 214 and the air-core coil 218. The magnification correction is executed by the electrostatic lens 214 in the combination of the electrostatic lens 214 and the air-core coil 218.

Consequently, as shown in FIG. 11, the x-direction dimension passing through the center position of the beam array can be coincident with the design dimension. Furthermore, as a result of the rotation adjustment, as shown in FIG. 11, the displacement component which deviates in the y direction in proportion to the design coordinate in the x direction can be corrected.

The respect that the focus position of the multiple beams 20 is adjusted using the electrostatic lens 216, being different from the electrostatic lens 214, is the same as that of the first embodiment. Although the case of adjusting the focus position is here described, it is also preferable to adjust a crossover position. For example, the final crossover position may be adjusted.

According to the second embodiment, since the beam array shape is corrected using the air-core coil 218 where no hysteresis occurs, and the electrostatic lens 214 where also no hysteresis occurs, the reproducibility is sufficient enough to omit the operation of confirming the shape.

The contents of each step after the dose map generation step (S120) are the same as those of the first embodiment.

Embodiments have been explained referring to specific examples described above. However, the present invention is not limited to these specific examples.

While the apparatus configuration, control method, and the like not directly necessary for explaining the present invention are not described, some or all of them can be appropriately selected and used on a case-by-case basis when needed. For example, although description of the configuration of the control unit for controlling the writing apparatus 100 is omitted, it should be understood that some or all of the configuration of the control unit can be selected and used appropriately when necessary.

Furthermore, any multi-charged particle beam writing apparatus and multi-charged particle beam writing method that include elements of the present invention and that can be appropriately modified by those skilled in the art are included within the scope of the present invention.

Additional advantages and modification will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A multi-charged particle beam writing method comprising:
acquiring a beam array shape of multiple charged particle beams;
calculating a magnification correction amount of an acquired beam array shape by using a first coefficient indicating a displacement component which deviates in a first direction in proportion to a design coordinate in the first direction of the acquired beam array shape, where the first direction is parallel to a direction of writing performed while continuously moving a stage with a target object thereon;
calculating a rotation correction amount of the acquired beam array shape by using a second coefficient indicating a displacement component which deviates in a second direction, being orthogonal to the first direction, in proportion to a design coordinate in the first direction of the acquired beam array shape;
calculating a modulation dose amount for each unit region of a plurality of unit regions obtained by dividing a stripe region of the target object into mesh regions, based on at least one of a third coefficient indicating a displacement component which deviates in the first direction in proportion to a design coordinate in the second direction of the acquired beam array shape, and a fourth coefficient indicating a displacement component which deviates in the second direction in proportion to a design coordinate in the second direction of the acquired beam array shape;
performing, using at least two objective lenses, at least one of rotation correction, corresponding to the rotation correction amount, of the acquired beam array shape, and magnification correction, corresponding to the magnification correction amount, of the acquired beam array shape, and performing modulation of a dose amount for the each unit region by using the modulation dose amount; and
writing a pattern on the target object with the multiple charged particle beams for which the modulation of the dose amount and at least the one of the rotation correction of the acquired beam array shape and the magnification correction of the acquired beam array shape have been performed.

2. The method according to claim 1, wherein the calculating the modulation dose amount includes
calculating a first modulation coefficient for the each unit region by using the third coefficient,
calculating a second modulation coefficient for the each unit region by using the fourth coefficient, and
calculating the modulation dose amount for the each unit region by using the dose amount for the each unit region, and using at least one of the first modulation coefficient and the second modulation coefficient.

3. The method according to claim 1, wherein the objective lenses include an electrostatic lens.

4. The method according to claim 3, further comprising:
adjusting one of a crossover position and a focus position of the multiple charged particle beams by using another electrostatic lens being different from the electrostatic lens.

5. The method according to claim 1, wherein an upper limit is set for the rotation correction amount.

6. A multi-charged particle beam writing apparatus comprising:
an emission source configured to emit multiple charged particle beams;
an acquisition circuit configured to acquire a beam array shape of the multiple charged particle beams;
a magnification correction amount calculation circuit configured to calculate a magnification correction amount of an acquired beam array shape by using a first coefficient indicating a displacement component which deviates in a first direction in proportion to a design coordinate in the first direction of the acquired beam array shape, where the first direction is parallel to a direction of writing performed while continuously moving a stage with a target object thereon;
a rotation correction amount calculation circuit configured to calculate a rotation correction amount of the acquired beam array shape by using a second coefficient indicating a displacement component which deviates in a second direction, being orthogonal to the first direction, in proportion to a design coordinate in the first direction of the acquired beam array shape;
a modulation dose amount calculation circuit configured to calculate a modulation dose amount for each unit region of a plurality of unit regions obtained by dividing a stripe region of the target object into mesh regions, based on at least one of a third coefficient indicating a displacement component which deviates in the first direction in proportion to a design coordinate in the second direction of the acquired beam array shape, and a fourth coefficient indicating a displacement component which deviates in the second direction in proportion to a design coordinate in the second direction of the acquired beam array shape;
a dose modulation circuit configured to perform modulation of a dose amount for the each unit region by using the modulation dose amount;
an objective lens configured to perform at least one of magnification correction, corresponding to the magnification correction amount, of the acquired beam array shape, and rotation correction, corresponding to the rotation correction amount, of the acquired beam array shape; and
a writing mechanism configured to write a pattern on the target object with the multiple charged particle beams for which the modulation of the dose amount and at least the one of the magnification correction of the acquired beam array shape and the rotation correction of the acquired beam array shape have been performed.
